(19) United States
(12) Patent Application Publication
(10) Pub. No.: US 2015/0035162 A1
(43) Pub. Date: Feb. 5, 2015

(54) INDUCTIVE DEVICE THAT INCLUDES CONDUCTIVE VIA AND METAL LAYER

(71) Applicant: QUALCOMM Incorporated, San Diego, CA (US)

(72) Inventors: Je-Hsiung Lan, San Diego, CA (US); Chengjie Zuo, Santee, CA (US); Mario Francisco Velez, San Diego, CA (US); Daeik D. Kim, San Diego, CA (US); David F. Berdy, West Lafayette, IN (US); Changhan Yun, San Diego, CA (US); Robert P. Mikulka, Oceanside, CA (US); Jonghae Kim, San Diego, CA (US); Matthew M. Nowak, San Diego, CA (US)

(73) Assignee: QUALCOMM Incorporated, San Diego, CA (US)

(21) Appl. No.: 13/957,462

(22) Filed: Aug. 2, 2013

(51) Int. Cl. H01L 23/522; G06F 17/50; H01L 21/768

(52) U.S. Cl. CPC H01L 23/5226; H01L 21/76897; G06F 17/5068
USPC 257/774; 438/667; 716/110

(57) ABSTRACT

An inductive device that includes a conductive via and a metal layer are disclosed. A particular method of forming an electronic device includes forming a metal layer that contacts a surface of a substrate. The substrate, including the surface, is formed from a substantially uniform dielectric material. The metal layer contacts a conductive via that extends at least partially within the substrate. The metal layer and the conductive via form at least a portion of an inductive device.

### I. FIELD

The present disclosure is generally related to an inductive device that includes a conductive via and a metal layer.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Integrated circuit manufacturing processes enable integration of a large number of microelectronic devices on an integrated circuit (IC). Such IC manufacturing technology has helped reduce costs associated with manufacturing wireless computing devices.

An electronic device (e.g., a diplexer) for use in wireless computing devices may be formed using IC manufacturing technology (such as through-glass-via (TGV) technology) to provide smaller size, higher performance, and cost advantages as compared to multi-layer chip diplexer (MLCD) technology. TGV technology involves fabrication of a via in substrate. The via may be at least partially filled with a conductive material (e.g., copper). Conventional wafer fabrication processes may include forming a buffer oxide layer on surfaces of the substrate to reduce surface oxidation associated with the substrate and the conductive material and to reduce reactivity of the substrate and the conductive material to subsequent process steps that may otherwise degrade the substrate and the conductive material. Surface oxidation and material degradation may result in a lower quality factor associated with the electronic device. However, the buffer oxide layer may reduce electrical connectivity between the conductive material and layers formed above the buffer oxide layer unless steps are taken to remove at least a portion of the buffer oxide layer. For example, portions of the buffer oxide layer may be removed by using a mask to pattern a photolithography layer on the substrate and by using an etch process to remove the buffer oxide layer in areas exposed in the photolithography layer.

### III. SUMMARY

This disclosure presents embodiments of a system that includes a substrate and an inductive device that includes a conductive via and a metal layer. The conductive via may extend at least partially within the substrate. The metal layer may contact the conductive via and a surface of the substrate (e.g., the substrate does not include a buffer oxide layer). An electronic device that includes the system may be formed using fewer masks and fewer processing steps, as compared to forming the electronic device on a substrate that includes the buffer oxide layer. Forming an electronic device where at least one metal layer directly contacts the substrate may protect against oxidation of a material of the conductive via without the need for a buffer oxide layer.

In a particular embodiment, a method of forming an electronic device includes forming a first metal layer that contacts a first surface of a substrate. The substrate, including the first surface, is formed from a substantially uniform dielectric material. The first metal layer contacts a first conductive via that extends at least partially within the substrate. The first metal layer and the first conductive via form at least a portion of an inductive device.

In another particular embodiment, a device includes a substrate. The device further includes a first conductive via that extends at least partially within the substrate. The device further includes a first metal layer that contacts a first surface of the substrate and contacts the conductive via. The substrate, including the first surface, is formed from a substantially uniform dielectric material. The first metal layer and the first conductive via form at least a portion of an inductive device.

In another particular embodiment, a method of forming an electronic device includes a step for forming a conductive via that extends at least partially within a substrate. The method further includes a step for forming a metal layer that contacts a surface of the substrate. The substrate, including the surface, is formed from a substantially uniform dielectric material. The metal layer contacts a conductive via that extends at least partially within the substrate. The metal layer and the conductive via form at least a portion of an inductive device.

In another particular embodiment, a device includes means for supporting layers. The device further includes means for connecting layers that extends at least partially within the means for supporting layers. The device further includes means for conducting. The means for conducting contacts a surface of the means for supporting layers and contacts the means for connecting layers. The means for supporting layers, including the surface, is formed from a substantially uniform dielectric material. The means for conducting and the means for connecting layers form at least a portion of an inductive device.

In another particular embodiment, a non-transitory computer readable medium includes instructions that, when executed by a processor, cause the processor to initiate formation of a metal layer that contacts a surface of a substrate. The substrate, including the surface, is formed from a substantially uniform dielectric material. The metal layer contacts a conductive via that extends at least partially within the substrate. The metal layer and the conductive via form at least a portion of an inductive device.

In another particular embodiment, a method includes receiving a data file including design information corresponding to an integrated circuit device. The method further includes fabricating the integrated circuit device according to the design information. The integrated circuit device includes a substrate. The integrated circuit device further includes a conductive via that extends at least partially within the substrate. The integrated circuit device further includes a metal layer that contacts a surface of the substrate and contacts the conductive via. The substrate, including the surface, is formed from a substantially uniform dielectric material. The metal layer contacts a conductive via that extends at least partially within the substrate. The metal layer and the conductive via form at least a portion of an inductive device.

One particular advantage provided by at least one of the disclosed embodiments is that an electronic device where at least one metal layer directly contacts a substrate may be formed using fewer masks and fewer processing steps, as compared to forming the electronic device on a substrate that includes the buffer oxide layer. Additionally, forming an electronic device where at least one metal layer directly contacts the substrate may protect against oxidation of a material of the conductive via without the need for a buffer oxide layer.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram showing a particular embodiment of a system including a plurality of electronic devices formed on a substrate;

FIG. 2 is a diagram showing several embodiments of manufacturing process flows to form electronic devices;

FIG. 3 is a diagram showing a particular embodiment of a diplexer;

FIG. 4 is a flow chart of a particular illustrative embodiment of a method of forming an electronic device;

FIG. 5 is a block diagram of a communication device including a substrate and an inductive device that includes a conductive via and a metal layer; and

FIG. 6 is a data flow diagram of a particular illustrative embodiment of a manufacturing process to manufacture electronic devices that include a substrate and an inductive device that includes a conductive via and a metal layer.

### V. DETAILED DESCRIPTION

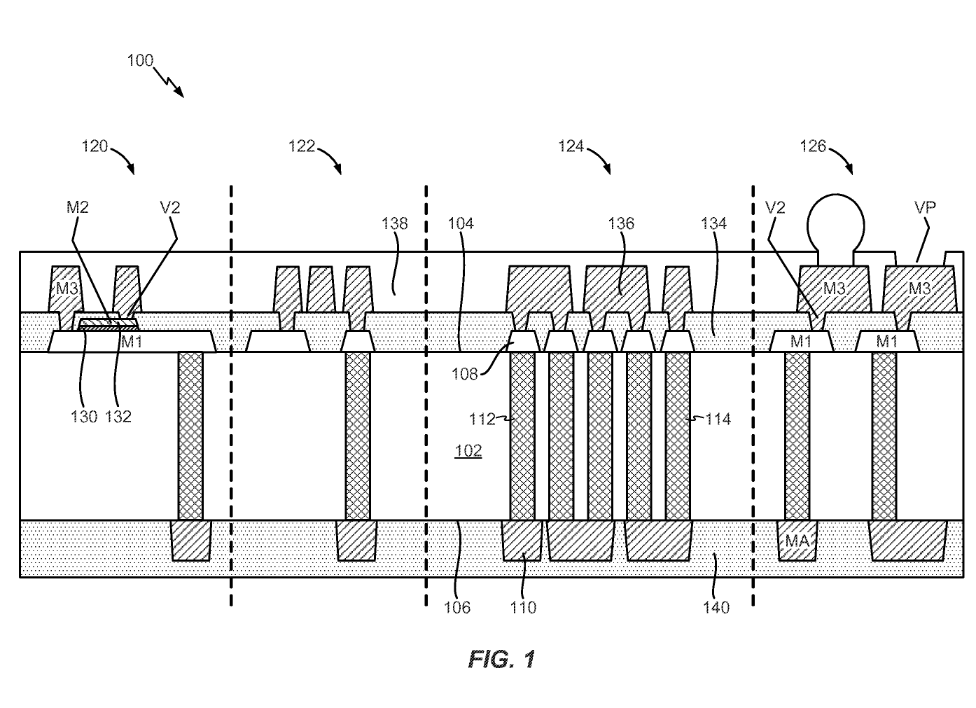

FIG. 1 illustrates a system 100 including a plurality of electronic devices formed on a substrate 102. Each electronic device of the system 100 can include the substrate 102 (or a portion of the substrate 102), one or more conductive vias (e.g., a first conductive via 112 and/or a second conductive via 114), at least one metal layer (e.g., a first metal layer 108, a second metal layer 110, a third metal layer 132, or a fourth metal layer 136), and at least one insulation layer (e.g., an interlayer dielectric (ILLS) 134, a metal insulator metal (MIM) dielectric layer 130, a first passivation layer 138, or a second passivation layer 140). The conductive vias 112, 114 may extend at least partially within the substrate 102 (e.g., entirely or partially through the substrate). For example, the substrate 102 may include a first surface 104 and a second surface 106, and the conductive vias 112, 114 may extend from the first surface 104 to the second surface 106.

In a particular embodiment, the substrate 102 is substantially uniform. For example, the substrate 102 may not include a protective outer layer, such as a buffer oxide layer (i.e., the substrate is an unprotected substrate). In another example, the substrate 102 may initially include a protective outer layer; however, the protective outer layer may be removed from at least a portion the first and second surfaces 104 106 and from at least one of the conductive vias (e.g., the first conductive via 112 and/or the second conductive via 114) before the at least one metal layer is formed. In this example, the protective outer layer may be removed without using a photolithography mask. Thus, when the at least one metal layer is formed, the substrate 102, including the at least one surface, may be formed from a substantially uniform dielectric material (i.e., the substrate 102 may be formed from a dielectric material with no buffer oxide layer or with trace amounts of a buffer oxide layer). Since the substrate 102 does not include a protective outer layer, the first metal layer 108 may directly contact the first surface 104 and the one or more conductive vias (e.g., the first conductive via 112 and/or the second conductive via 114), and the second metal layer 110 may directly contact the second surface 106 and the one or more conductive vias (e.g., the first conductive via 112 and/or the second conductive via 114). In a particular embodiment, the first metal layer 108 and the first conductive via 112 form at least a portion of an inductive device (e.g., an inductor formed in a third region 124).

The substrate 102 may be formed of a glass material, an alkaline earth boro-aluminosilicate glass, Gallium Arsenide (GaAs), Indium phosphate (InP), silicon carbide (SiC), a glass-based laminate (e.g., a high frequency laminate available from the Rogers corporation), sapphire (Al₂O₃), quartz, a ceramic, silicon on insulator (SOI), silicon on sapphire (SOS), high resistivity silicon (HRS), aluminum nitride (MN), a plastic, or a combination thereof. In a particular embodiment, the substrate 102 has a thickness of at least 0.1 millimeter (mm) (e.g., between 0.1 mm and 0.5 mm).

In a particular embodiment, the first metal layer 108 is patterned to form at least a portion of an electronic device (e.g., an inductor or a capacitor). In a particular embodiment, the first conductive via 112 and the second conductive via. 114 contact the first metal layer 108. The first metal layer 108, the first conductive via 112, and the second conductive via 114 may form a portion of a coil of an inductive device (e.g., the inductor formed in the third region 124). The first metal layer 108 may protect against oxidation of a material of the first conductive via 112 by covering at least a portion of the first conductive via 112. The first metal layer 108 may be formed of aluminum, copper, silver, gold, tungsten, molybdenum, an alloy of aluminum, copper, silver, gold, tungsten, or molybdenum, or a combination thereof. In a particular embodiment, the first metal layer 108 is formed of aluminum and has a thickness of 3 micrometers (μm). In a particular embodiment, the conductive vias 112, 114 are through glass vias (TGVs). The conductive vias 112, 114 may be formed of copper, tungsten, silver, gold, an alloy of copper, tungsten, silver, or gold, or a combination thereof. The first metal layer 108 may be formed of a different material than the first conductive via 112. The conductive vias 112, 114 may be formed using laser drilling, sand blasting, photolithography, light-induced etching, or a combination thereof. In a particular embodiment, the conductive vias 112, 114 have a diameter of approximately 70 μm.

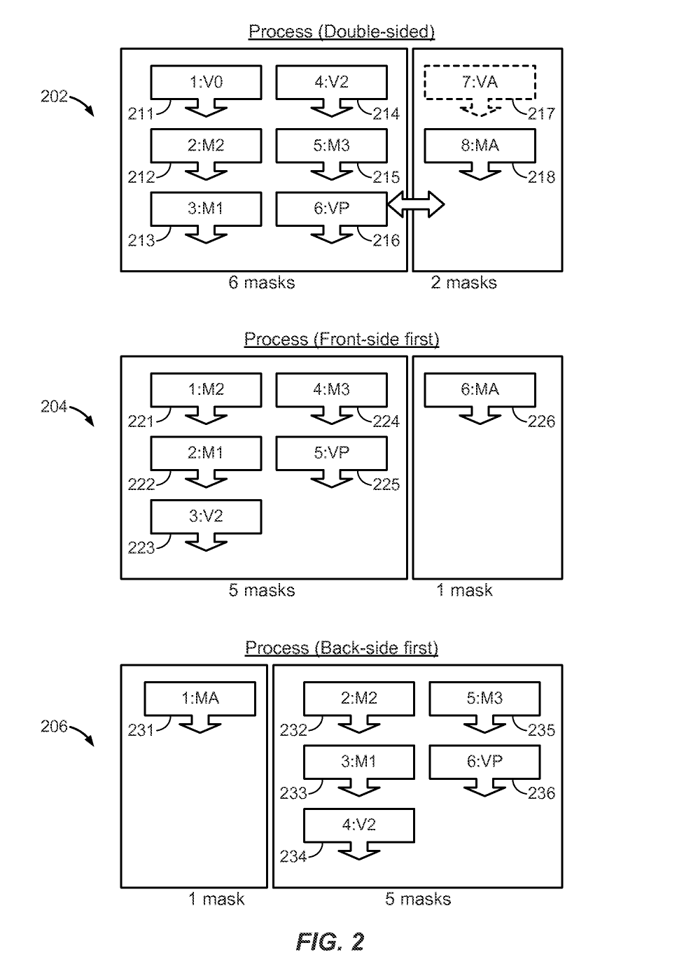

In a particular embodiment, the first conductive via 112 and the second surface 106 contact the second metal layer 110. The second surface 106 may be opposite the first surface 104. The conductive vias 112, 114 may extend through the substrate 102. The second metal layer 110 may be patterned to form at least a portion of an electronic device (e.g., an inductor or a capacitor). In a particular embodiment, the first metal layer 108, the second metal layer 110, the first conductive via 112, and the second conductive via 114 may be connected to form a loop of an inductor (e.g., the inductor formed in the third region 124). The second metal layer 110 may protect against oxidation of a material of the first conductive via 112 by covering at least a portion of the first conductive via 112. The second metal layer 110 may be formed of a different material than the first conductive via 112 and may be formed of a different material than the first metal layer 108. The second metal layer 110 may be formed of aluminum, copper, silver, gold, tungsten, molybdenum, an alloy of aluminum, copper, silver, gold, tungsten, or molybdenum, or a combination thereof. In a particular embodiment, the second metal layer 110 is formed of copper and has a thickness between 10 μm and 15 μm. The second metal layer 110 may be formed before the first metal layer 108 (e.g., as shown by the process flow 206 of FIG. 2) or may be formed after the first metal layer 108 (e.g., as shown by the process flow 204 of FIG. 2).

Additional layers (e.g., layers M2, V2, M3, and VP) may be formed above the first metal layer 108, below the second metal layer 110, or both. In a particular embodiment, a capacitor (e.g., a capacitor formed in a first region 120) that includes the MIM dielectric layer 130 and the third metal layer 132, is formed above the first metal layer 108. In a particular embodiment, the MIM dielectric layer 130 is formed of SiO₂, SiNₓ, or SiOₓN_{y} using plasma-enhanced chemical vapor deposition (PECVD), formed of Al₂O₃ using physical vapor deposition (PVD) or atomic layer deposition (ALD), formed of ZrO₂ using ALD, formed of Ta₂O₅ by sputtering PVD of Ta before using an anodization process, or a combination thereof. As an illustrative example, the MIM dielectric layer 130 may be formed of Ta₂O₅ with a thickness of 0.23 μm. As another illustrative example, the MIM dielectric layer 130 may be formed of SiOₓ formed using PECVD with a thickness of 350 angstroms (Å). The third metal layer 132 may be formed of aluminum with a thickness of 1 μm. In a particular embodiment, the fourth metal layer 136 may be formed above the first metal layer 108, the third metal layer 132, or both. The fourth metal layer 136 may be formed of copper with a thickness between 10 μm and 15 μm. In a particular embodiment, ILD layers (e.g., the ILD 134) are formed between adjacent metal layers (e.g., between the first metal layer 108 and the fourth metal layer 136). The ILD 134 may be formed above the third metal layer 132 using a photo-definable polymer (e.g., polyimide (PI)) with a thickness of 5 μm. In a particular embodiment, passivation layers (e.g., the first passivation layer 138 and the second passivation layer 140) are formed on a top of the system 100 and on a bottom of the system 100. The passivation layers 138, 140 may be formed of a photo-definable polymer with a thickness between 20 μm and 25 μm.

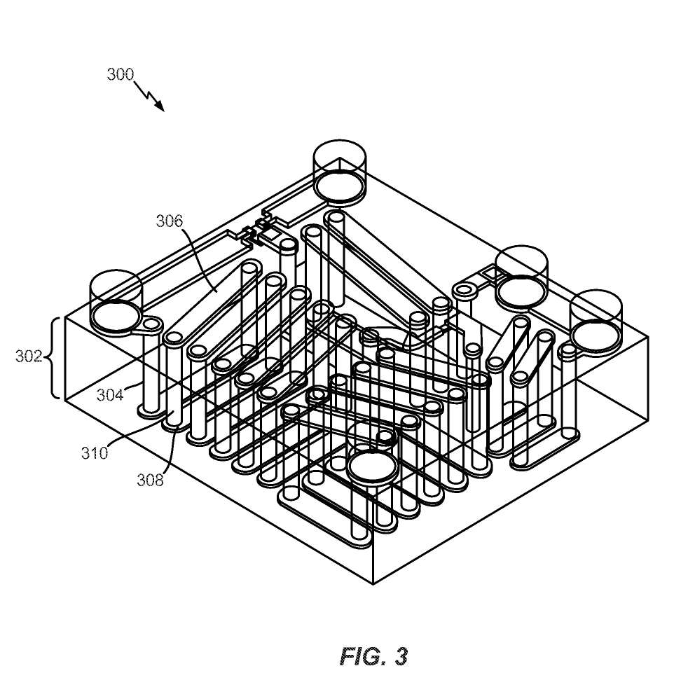

FIG. 1 is divided into several regions 120-126. Each region 120-126 illustrates the formation of a different device. For example, the first region 120 illustrates the formation of a capacitor. A second region 122 illustrates the formation of an inductor or a lateral-coupling hybrid transformer. The third region 124 illustrates the formation of an inductor (e.g., a three dimensional TGV-based inductor). A fourth region 126 illustrates the formation of a ball pad and a probe pad. The regions 120-126 may be arranged in any configuration and integrated in an electronic device (e.g., a diplexer as shown in FIG. 3). In a particular embodiment, the regions 120-126 are arranged to form a diplexer (e.g., the diplexer of FIG. 3), a low-pass radio frequency (RF) filter, a high-pass RF filter, a notch RF filter, or a harmonic trap circuit.

Forming an electronic device incorporating the system 100 may protect against oxidation of a material of the conductive via without the need for a buffer oxide layer.

FIG. 2 illustrates several embodiments of manufacturing process flows to form electronic devices. The represented manufacturing processes illustrate differences between forming the electronic devices of FIG. 1 when a buffer oxide layer is present as compared to when the substrate does not include a buffer oxide layer. For example, the manufacturing processes include a first process flow 202 to manufacture an electronic device when a buffer oxide layer is present on a substrate. The manufacturing processes also include a second process flow 204 to manufacture an electronic device when no buffer oxide layer is present on the substrate (e.g., the substrate 102) and when metal layers (e.g., the first metal layer 108 of FIG. 1) are formed above a first surface of the substrate before metal layers (e.g., the second metal layer 110 of FIG. 1) are formed below a second surface of the substrate, where the second surface is opposite the first surface. The manufacturing processes also include a third process flow 206 to manufacture an electronic device when no buffer oxide layer is present on the substrate (e.g., the substrate 102) and when metal layers (e.g., the second metal layer 110 of FIG. 1) are formed above a second surface of the substrate before metal layers (e.g., the first metal layer 108 of FIG. 1) are formed below a first surface of the substrate, where the second surface is opposite the first surface. The steps of the process flows 202, 204, and 206 of FIG. 2 may correspond to metal layers and vias FIG. 1.

The illustrated manufacturing processes of FIG. 2 show masks (e.g., photolithography masks) used to form layers on the substrate. In particular, the first process flow 202 illustrates a first mask 211 used to pattern a photolithography layer to etch openings in a buffer oxide layer to provide access through the buffer oxide layer to one or more of the conductive vias (e.g., the first conductive via 112 and/or the second conductive via 114 of FIG. 1). After the openings (V0) are formed (e.g., using an etch process) through the buffer oxide layer, the openings may be filled with a conductive metal during application of a first metal layer (M1). The first metal layer (M1) may provide a conductive path from one or more of the conductive vias to an upper surface of the buffer oxide layer. After the first metal layer (M1) is applied, a dielectric layer (e.g., as shown in the first region 120 of FIG. 1) and a second metal layer (M2) may be applied above the first metal layer (M1). A second mask 212 may be used to form a photolithography layer used to pattern the second metal layer (M2). The second metal layer (M2) may be a portion of one or more electronic devices (e.g., devices including regions 120-126 of FIG. 1). After the second metal layer (M2) is patterned, a third mask 213 may be used to form a photolithography layer used to pattern the first metal layer (M1). The first metal layer (M1) may be a portion of one or more electronic devices (e.g., devices including the regions 120-126 of FIG. 1). A first passivation layer may be formed over the first metal layer (M1) and the second metal layer (M2).

In the first process flow 202 illustrated in FIG. 2, after the first passivation layer is formed, a fourth mask 214, may be used to form a photolithography layer used to pattern openings in the first passivation layer. After the openings are formed in the first passivation layer (e.g., using an etch process), the openings may be filled with a conductive metal during application of a third metal layer (M3). The third metal layer (M3) may provide a conductive path from one or more of the conductive vias, the first metal layer (M1), or the second metal layer (M2) to an upper surface of the first passivation layer. After the third metal layer (M3) is applied, a fifth mask 215 may be used to form a photolithography layer used to pattern the third metal layer (M3). The third metal layer (M3) may be a portion of one or more electronic devices (e.g., devices including the regions 120-126 of FIG. 1). A second passivation layer may be formed over the third metal layer (M3).

In the first process flow 202 illustrated in FIG. 2, after the second passivation layer is formed, a sixth mask 216 may be used to form openings in the second passivation layer. After the openings are formed in the second passivation layer (e.g., using an etch process), the openings may be filled with a conductive metal (e.g., during application or formation of solder balls). Thus, a conductive path may be provided from one or more of the conductive vias, the first metal layer (M1), the second metal layer (M2), or the third metal layer (M3) to an upper surface of the second passivation layer.

Further, in the first process flow 202 illustrated in FIG. 2, after the metal layers are applied on a first side of the substrate, the substrate may be flipped and a seventh mask 217 may be used to pattern a photolithography layer to etch openings in a buffer oxide layer on a second side of the substrate to provide access through the buffer oxide layer to one or more of the conductive vias. After the openings are formed (e.g., using an etch process) through the buffer oxide layer on the second side of the substrate, the openings may be filled with a conductive metal during application of a bottom metal layer (MA). The bottom metal layer (MA) may provide a conductive path from one or more of the conductive vias to an upper surface of the buffer oxide layer. After the bottom metal layer (MA) is applied, an eighth mask 218 may be used to form a photolithography layer used to pattern a bottom metal layer (MA). The bottom metal layer (MA) may be a portion of one or more electronic devices (e.g., devices including the regions 120-126 of FIG. 1). A third passivation layer may be formed over the bottom metal layer (MA). Thus, eight masks may be used to manufacture the electronic devices illustrated in FIG. 1 on a substrate that includes a buffer oxide layer using the first process flow 202 illustrated in FIG. 2. Although the first process flow 202 illustrates forming openings and layers on the first side of the substrate (e.g., using masks 211-216) before forming openings and layers on the second side of the substrate (e.g., using the seventh mask 217 and the eighth mask 218), openings and layers may instead be formed on the second side of the substrate before forming openings and layers on the first side of the substrate.

The second process flow 204 illustrates formation of one or more electronic devices on a substrate (e.g., the substrate 102 of FIG. 1) that does not include a protective layer, such as a buffer oxide layer. The substrate may be formed of a substantially uniform dielectric material. In the second process flow 204, a first metal layer (M1) is applied directly over the substrate and the conductive vias (e.g., the first conductive via. 112 and/or the second conductive via 114 of FIG. 1). The first metal layer (M1) may directly contact the substrate and one or more of the conductive vias. After the first metal layer (M1) is applied, a dielectric layer (e.g., as shown in the first region 120 of FIG. 1) and a second metal layer (M2) may be applied above the first metal layer (M1). After the second metal layer (M2) is applied, a first mask 221 is used to form a photolithography layer used to pattern the second metal layer (M2). The second metal layer (M2) may be a portion of one or more electronic devices (e.g., devices including the regions 120-126 of FIG. 1). After the second metal layer (M2) is patterned, a second mask 222 may be used to form a photolithography layer used to pattern the first metal layer (M1). The first metal layer (M1) may be a portion of one or more electronic devices (e.g., devices including the regions 120-126 of FIG. 1). A first passivation layer may be formed over the first metal layer (M1) and the second metal layer (M2).

In the second process flow 204 illustrated in FIG. 2, after the first passivation layer is formed, a third mask 223 may be used to form a photolithography layer used to pattern openings in the first passivation layer. After the openings are formed in the first passivation layer (e.g., using an etch process), the openings may be filled with a conductive metal during application of a third metal layer (M3). The third metal layer (M3) may provide a conductive path from one or more of the conductive vias, the first metal layer (M1), or the second metal layer (M2) to an upper surface of the first passivation layer. After the third metal layer (M3) is applied, a fourth mask 224 may be used to form a photolithography layer used to pattern the third metal layer (M3). The third metal layer (M3) may be a portion of one or more electronic devices (e.g., devices including the regions 120-126 of FIG. 1). A second passivation layer may be formed over the third metal layer (M3).

In the second process flow 204 illustrated in FIG. 2, after the second passivation layer is formed, a fifth mask 225 may be used to form openings in the second passivation layer. After the openings are formed in the second passivation layer (e.g., using an etch process), the openings may be filled with a conductive metal (e.g., during application or formation of solder bumps). Thus, a conductive path may be provided from one or more of the conductive vias, the first metal layer (M1), the second metal layer (M2), or the third metal layer (M3) to an upper surface of the second passivation layer.

Further, in the second process flow 204 illustrated in FIG. 2, after the metal layers are applied on a first side of the substrate, the substrate may be flipped and a bottom metal layer (MA) may be applied to a second side of the substrate. After the bottom metal layer (MA) is applied, a sixth mask 226 may be used to form a photolithography layer used to pattern the bottom metal layer (MA). The bottom metal layer (MA) may directly contact the substrate and one or more of the conductive vias. The bottom metal layer (MA) may be a portion of one or more electronic devices (e.g., devices including the regions 120-126 of FIG. 1). A third passivation layer may be formed over the bottom metal layer (MA). Thus, six masks may be used to manufacture the electronic devices illustrated in FIG. 1 on a substrate that does not include a buffer oxide layer using the second process flow 204 illustrated in FIG. 2, as compared to the eight masks of the first process flow 202.

The third process flow 206 illustrates formation of one or more electronic devices on a substrate (e.g., the substrate 102 of FIG. 1) that does not include a protective layer, such as a buffer oxide layer. The substrate may be formed of a substantially uniform dielectric material. In the third process flow 206, a bottom metal layer (MA) is applied directly over the substrate and one or more conductive vias the first conductive via 112 and/or the second conductive via 114 of FIG. 1). After the bottom metal layer (MA) is applied, a first mask 231 is used to form a photolithography layer used to pattern the bottom metal layer (MA). The bottom metal layer (MA) may directly contact the substrate and one or more of the conductive vias. The bottom metal layer (MA) may be a portion of one or more electronic devices (e.g., devices including the regions 120-126 of FIG. 1). A third passivation layer may be formed over the bottom metal layer (MA).

Further, in the third process flow 206 illustrated in FIG. 2, after the third passivation layer is formed on a first side of the substrate, the substrate may be flipped and a first metal layer (M1) may be applied to a second side of the substrate directly over the substrate and one or more of the conductive vias. The first metal layer (M1) may directly contact the substrate and one or more of the conductive vias. After the first metal layer (M1) is applied, a dielectric layer (e.g., as shown in the first region 120 of FIG. 1) and a second metal layer (M2) may be applied above the first metal layer (M1). After the second metal layer (M2) is applied, a second mask 232 may be used to form a photolithography layer used to pattern the second metal layer (M2). The second metal layer (M2) may be a portion of one or more electronic devices (e.g., devices including the regions 120-126 of FIG. 1). After the second metal layer (M2) is formed, a third mask 233 may be used to form a photolithography layer used to pattern the first metal layer (M1). The first metal layer (M1) may be a portion of one or more electronic devices (e.g., devices including the regions 120-126 of FIG. 1). A first passivation layer may be formed over the first metal layer (M1) and the second metal layer (M2).

In the third process flow 206 illustrated in FIG. 2, after the first passivation layer is formed, a fourth mask 234 may be used to form a photolithography layer used to pattern openings in the first passivation layer. After the openings are formed in the first passivation layer (e.g., using an etch process), the openings may be filled with a conductive metal during application of a third metal layer (M3). The third metal layer (M3) may provide a conductive path from one or more of the conductive vias, the first metal layer (M1), or the second metal layer (M2) to an upper surface of the first passivation layer. After the third metal layer (M3) is applied, a fifth mask 235 may be used to form a photolithography layer used to pattern the third metal layer (M3). The third metal layer (M3) may be a portion of one or more electronic devices (e.g., devices including the regions 120-126 of FIG. 1). A second passivation layer may be formed over the third metal layer (M3).

In the third process flow 206 illustrated in FIG. 2, after the second passivation layer is formed, a sixth mask 236 may be used to form openings in the second passivation layer. After the openings are formed in the second passivation layer (e.g., using an etch process), the openings may be filled with a conductive metal (e.g., during application or formation of solder balls). Thus, a conductive path may be provided from one or more of the conductive vias, the first metal layer (M1), the second metal layer (M2), or the third metal layer (M3) to an upper surface of the second passivation layer. Thus, six masks may be used to manufacture the electronic devices illustrated in FIG. 1 on a substrate that does not include a buffer oxide layer using the third process flow 206 illustrated in FIG. 2, as compared to the eight masks of the first process flow 202.

Forming an electronic device where at least one metal layer directly contacts the substrate (i.e., where the substrate does not include a buffer oxide layer) (e.g., using the second process flow 204 or the third process flow 206) may be fewer masks and fewer processing steps, as compared to forming an electronic device on a substrate that includes a buffer oxide layer (e.g., using the first process flow 202). Forming an electronic device where at least one metal layer directly contacts the substrate may protect against oxidation of a material of the conductive via without the need for a buffer oxide layer. When electronic devices other than those included in the system 100 of FIG. 1 are created, more layers, fewer layers, or different layers may be used, depending on the specific electronic device or devices being formed. For example, an electronic device may include additional metal layers or layers of other materials, such as semiconductor materials.

FIG. 3 illustrates a particular illustrative embodiment of a diplexer 300. The diplexer 300 includes an inductor 304 formed through a substrate 302. The substrate 302 may be formed of a glass material. The substrate 302 may correspond to the substrate 102 of FIG. 1. The inductor 304 may correspond to the inductor formed in the third region 124 of FIG. 1. In the embodiment illustrated FIG. 3, the inductor 304 includes portions of a first metal layer 306, portions of a second metal layer 308, and a plurality of conductive vias (e.g., conductive via 310). The first metal layer 306 may correspond to the first metal layer 108 or the second metal layer 110 of FIG. 1. The second metal layer 308 may correspond to the first metal layer 108 or the second metal layer 110 of FIG. 1. The conductive via 310 may correspond to the first conductive via 112 or the second conductive via 114 of FIG. 1. The first metal layer 306, the second metal layer 308, and the conductive via. 310 may form a portion of a coil of an inductive device (e.g., the inductor 304).

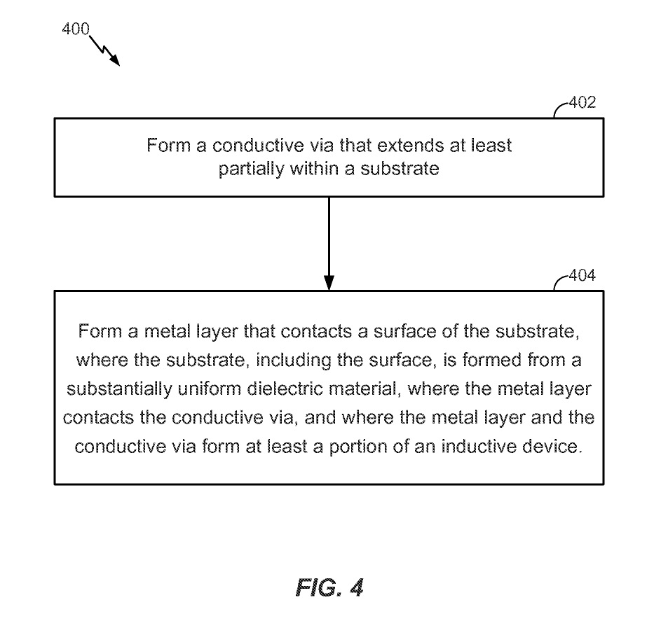

FIG. 4 is a flowchart illustrating a particular embodiment of a method 400 of forming an electronic device. The method 400 includes, at 402, forming a conductive via that extends at least partially within a substrate. For example, as described with reference to FIG. 1, the first conductive via 112 may be formed, where the first conductive via 112 extends at least partially within the substrate 102.

The method 400 further includes, at 404, forming a metal layer that contacts a surface of the substrate, where the substrate, including the surface, is formed from a substantially uniform dielectric material, where the metal layer contacts the conductive via, and where the metal layer and the conductive via form at least a portion of an inductive device. For example, the first metal layer 108 may be formed contacting the first surface 104 of the substrate 102. The substrate 102, including the first surface 104, may be formed from a substantially uniform dielectric material. The first metal layer 108 may contact the first conductive via 112. The first metal layer 108 and the first conductive via 112 form at least a portion of an inductive device (e.g., the inductor formed in the third region 124).

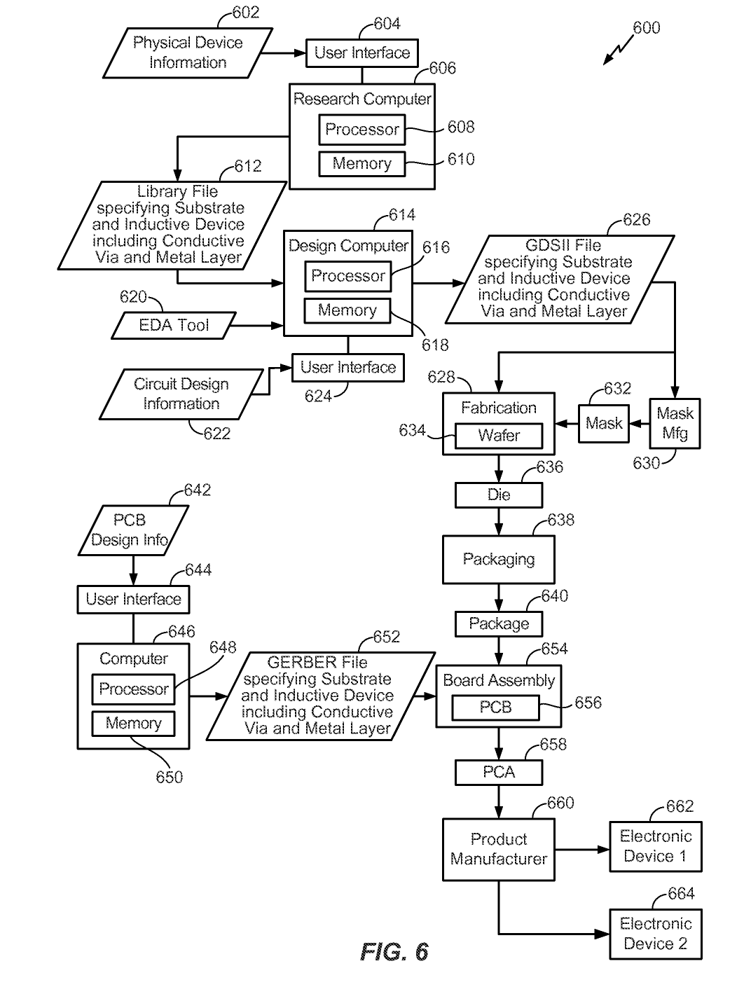

The method of FIG. 4 may be initiated by a field-programmable gate array (FPGA) device, an application-specific integrated circuit (ASIC), a processing unit such as a central processing unit (CPU), a digital signal processor (DSP), a controller, another hardware device, firmware device, or any combination thereof. As an example, the method of FIG. 4 can be initiated by integrated circuit fabrication equipment, such as a processor that executes instructions stored at a memory (e.g., a non-transitory computer-readable medium), as described further with reference to FIG. 6.

Forming an electronic device according to the method 400 where at least one metal layer directly contacts the substrate (i.e., where the substrate does not include a buffer oxide layer) may use fewer masks and fewer processing steps, as compared to forming an electronic device on a substrate that includes a buffer oxide layer. Forming an electronic device where at least one metal layer directly contacts the substrate may protect against oxidation of a material of the conductive via without the need for a buffer oxide layer.

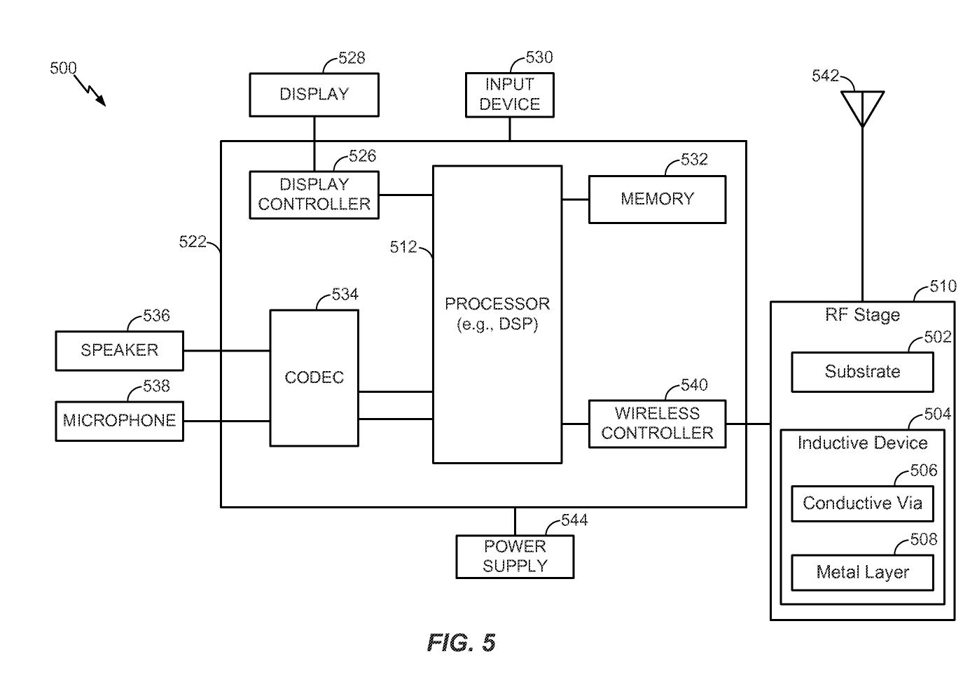

Referring to FIG. 5, a block diagram of a particular illustrative embodiment of a mobile device that includes a substrate 502 and an inductive device 504 including a conductive via 506 and a metal layer 508 is depicted and generally designated 500. The mobile device 500, or components thereof, may include, implement, or be included within a device such as: a mobile station, an access point, a set top box, an entertainment unit, a navigation device, a communications device, a personal digital assistant (PDA), a fixed location data unit, a mobile location data unit, a mobile phone, a cellular phone, a computer, a portable computer, a desktop computer, a tablet, a monitor, a computer monitor, a television, a tuner, a radio, a satellite radio, a music player, a digital music player, a portable music player, a video player, a digital video player, a digital video disc (DVD) player, or a portable digital video player.

The mobile device 500 may include a processor 512, such as a digital signal processor (DSP). The processor 512 may be coupled to a memory 532 (e.g., a non-transitory computer-readable medium).

FIG. 5 also shows a display controller 526 that is coupled to the processor 512 and to a display 528. A coder/decoder (CODEC) 534 can also be coupled to the processor 512. A speaker 536 and a microphone 538 can be coupled to the CODEC 534. A wireless controller 540 can be coupled to the processor 512 and can be further coupled to an RE stage 510 that includes the substrate 502 and the inductive device 504. The inductive device 504 may include a conductive via. 506 and a metal layer 508. The RF stage 510 may be coupled to an antenna 542. The metal layer 508 may contact the substrate 502 and contact the conductive via 506 and may protect against oxidation of a material of the conductive via 506 without the need for a buffer oxide layer. The substrate 502 may correspond to the substrate 102 of FIG. 1 or the substrate 302 of FIG. 3. The inductive device 504 may correspond to the inductor formed in the third region 124 of FIG. 1 or the inductor 304 of FIG. 3. The conductive via 506 may correspond to the first conductive via 112 of FIG. 1, the second conductive via 114 of FIG. 1, or the conductive via 310 of FIG. 3. The metal layer 508 may correspond to the first metal layer 108 of FIG. 1, the second metal layer 110 of FIG. 1, the first metal layer 306 of FIG. 3, or the second metal layer 308 of FIG. 3. In other embodiments, the substrate 502 and the inductive device 504 may be included in, or configured to provide inductance to, other components of the mobile device 500.

In a particular embodiment, the processor 512, the display controller 526, the memory 532, the CODEC 534, and the wireless controller 540 are included in a system-in-package or system-on-chip device 522. An input device 530 and a power supply 544 may be coupled to the system-on-chip device 522. Moreover, in a particular embodiment, and as illustrated in FIG. 5, the RF stage 510, the display 528, the input device 530, the speaker 536, the microphone 538, the antenna 542, and the power supply 544 are external to the system-on-chip device 522. However, each of the display 528, the input device 530, the speaker 536, the microphone 538, the antenna 542, and the power supply 544 can be coupled to a component of the system-on-chip device 522, such as an interface or a controller. The RF stage 510 may be included in the system-on-chip device 522 or may be a separate component.

In conjunction with the described embodiments, a device may include means for supporting layers, means for connecting layers that extends at least partially within the means for supporting layers, and means for conducting. The means for conducting may contact a surface of the means for supporting layers and contact the means for connecting layers. The means for supporting layers, including the surface, may be formed from a substantially uniform dielectric material. The means for conducting and the means for connecting layers may form at least a portion of an inductive device. The means for supporting layers may include the substrate 102 of FIG. 1 or the substrate 302 of FIG. 3. The means for connecting layers may include the first conductive via 112 of FIG. 1, the second conductive via 114 of FIG. 1, or the conductive via 310 of FIG. 3. The inductive device may correspond to the inductor formed in the third region 124 of FIG. 1 or the inductor 304 of FIG. 3.

The foregoing disclosed devices and functionalities may be designed and configured into computer files (e.g. RTL, GDSII, GERBER, etc.) stored on computer-readable media. Some or all such files may be provided to fabrication handlers to fabricate devices based on such files. Resulting products include wafers that are then cut into integrated circuit dies and packaged into integrated circuit chips. The integrated circuit chips are then integrated into electronic devices, as described further with reference to FIG. 6.

Referring to FIG. 6, a particular illustrative embodiment of an electronic device manufacturing process is depicted and generally designated 600. In FIG. 6, physical device information 602 is received at the manufacturing process 600, such as at a research computer 606. The physical device information 602 may include design information representing at least one physical property of an integrated circuit device, such as a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via. 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3). For example, the physical device information 602 may include physical parameters, material characteristics, and structure information that is entered via a user interface 604 coupled to the research computer 606. The research computer 606 includes a processor 608, such as one or more processing cores, coupled to a computer-readable medium such as a memory 610. The memory 610 may store computer-readable instructions that are executable to cause the processor 608 to transform the physical device information 602 to comply with a file format and to generate a library file 612.

In a particular embodiment, the library file 612 includes at least one data file including the transformed design information. For example, the library file 612 may include a library of integrated circuit devices, including a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), provided for use with an electronic design automation (FDA) tool 620.

The library file 612 may be used in conjunction with the FDA tool 620 at a design computer 614 including a processor 616, such as one or more processing cores, coupled to a memory 618. The EDA tool 620 may be stored as processor executable instructions at the memory 618 to enable a user of the design computer 614 to design a circuit including a substrate (e.g., corresponding to the substrate 102 of FIG. 1 or the substrate 302 of FIG. 3) and an inductive device corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), using the library file 612. For example, a user of the design computer 614 may enter circuit design information 622 via a user interface 624 coupled to the design computer 614. The circuit design information 622 may include design information representing at least one physical property of an integrated circuit device, such as a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via. 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3). To illustrate, the circuit design property may include identification of particular circuits and relationships to other elements in a circuit design, positioning information, feature size information, interconnection information, or other information representing a physical property of an integrated circuit device.

The design computer 614 may be configured to transform the design information, including the circuit design information 622, to comply with a file format. To illustrate, the file formation may include a database binary file format representing planar geometric shapes, text labels, and other information about a circuit layout in a hierarchical format, such as a Graphic Data System (GDSII) file format. The design computer 614 may be configured to generate a data file including the transformed design information, much as a GDSII file 626 that includes information describing a substrate corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), in addition to other circuits or information. To illustrate, the data file may include information corresponding to a system-on-chip (SOC) that includes a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via. 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), and that also includes additional electronic circuits and components within the SOC.

The GDSII file 626 may be received at a fabrication process 628 to manufacture a substrate corresponding to the substrate 102 of FIG. 1 or the substrate 302 of FIG. 3) and an inductive device corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3) according to transformed information in the GDSII file 626. For example, a device manufacture process may include providing the GDSII file 626 to a mask manufacturer 630 to create one or more masks, such as masks to be used with photolithography processing, illustrated in FIG. 6 as a representative mask 632. The mask 632 may be used during the fabrication process to generate one or more wafers 634, which may be tested and separated into dies, such as a representative die 636. The die 636 includes a circuit including a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3).

The die 636 may be provided to a packaging process 638 where the die 636 is incorporated into a representative package 640. For example, the package 640 may include the single die 636 or multiple dies, such as a system-in-package (SiP) arrangement. The package 640 may be configured to conform to one or more standards or specifications, such as Joint Electron Device Engineering Council (JEDEC) standards.

Information regarding the package 640 may be distributed to various product designers, such as via a component library stored at a computer 646. The computer 646 may include a processor 648, such as one or more processing cores, coupled to a memory 650. A printed circuit board (PCB) tool may be stored as processor executable instructions at the memory 650 to process PCB design information 642 received from a user of the computer 646 via a user interface 644. The PCB design information 642 may include physical positioning information of a packaged integrated circuit device on a circuit board, the packaged integrated circuit device corresponding to the package 640 including a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3).

The computer 646 may be configured to transform the PCB design information 642 to generate a data file, such as a GERBER file 652 with data that includes physical positioning information of a packaged integrated circuit device on a circuit board, as well as layout of electrical connections such as traces and vias, where the packaged integrated circuit device corresponds to the package 640 including a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3). In other embodiments, the data file generated by the transformed PCB design information may have a format other than a GERBER format.

The GERBER file 652 may be received at a board assembly process 654 and used to create PCBs, such as a representative PCB 656, manufactured in accordance with the design information stored within the GERBER file 652. For example, the GERBER file 652 may be uploaded to one or more machines to perform various steps of a PCB production process. The PCB 656 may be populated with electronic components including the package 640 to form a representative printed circuit assembly (PCA) 658.

The PCA 658 may be received at a product manufacturer 660 and integrated into one or more electronic devices, such as a first representative electronic device 662 and a second representative electronic device 664. As an illustrative, non-limiting example, the first representative electronic device 662, the second representative electronic device 664, or both, may be selected from a set top box, a music player, a video player, an entertainment unit, a navigation device, a communications device, a personal digital assistant (PDA), a fixed location data unit, and a computer, into which a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), are integrated. As another illustrative, non-limiting example, one or more of the electronic devices 662 and 664 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 6 illustrates remote units according to teachings of the disclosure, the disclosure is not limited to these illustrated units Embodiments of the disclosure may be suitably employed in any device which includes active integrated circuitry including memory and on-chip circuitry.

A device that includes a substrate (e.g., corresponding to the substrate 102 of FIG. 1 or the substrate 302 of FIG. 3) and an inductive device (e.g., corresponding to the inductor formed in the third region 124 of FIG. 1 or the inductor 304 of FIG. 3) including a conductive via (e.g., corresponding to the first conductive via 112 of FIG. 1, the second conductive via 114 of FIG. 1, or the conductive via 310 of FIG. 3) and a metal layer (e.g., corresponding to the first metal layer 108 of FIG. 1, the second metal layer 110 of FIG. 1, the first metal layer 306 of FIG. 3, or the second metal layer 308 of FIG. 3), may be fabricated, processed, and incorporated into an electronic device, as described in the illustrative manufacturing process 600. One or more aspects of the embodiments disclosed with respect to FIGS. 1-5 may be included at various processing stages, such as within the library file 612, the GDSII file 626, and the GERBER file 652, as well as stored at the memory 610 of the research computer 606, the memory 618 of the design computer 614, the memory 650 of the computer 646, the memory of one or more other computers or processors (not shown) used at the various stages, such as at the board assembly process 654, and also incorporated into one or more other physical embodiments such as the mask 632, the die 636, the package 640, the PCA 658, other products such as prototype circuits or devices (not shown), or any combination thereof. Although various representative stages are depicted with reference to FIGS. 1-5, in other embodiments fewer stages may be used or additional stages may be included. Similarly, the process 600 of FIG. 6 may be performed by a single entity or by one or more entities performing various stages of the manufacturing process 600.

In conjunction with the described embodiments, a non-transitory computer-readable medium stores instructions that, when executed by a processor, cause the processor to initiate formation of a metal layer that contacts a surface of a substrate. The substrate, including the surface, may be formed from a substantially uniform dielectric material. The metal layer may contact a conductive via that extends at least partially within the substrate. The metal layer and the conductive via may form at least a portion of an inductive device. The non-transitory computer-readable medium may correspond to the memory 532 of FIG. 5 or to the memory 610, the memory 618, or the memory 650 of FIG. 6. The processor may correspond to the processor 512 of FIG. 5 or to the processor 608, the processor 616, or the processor 648 of FIG. 6. The substrate may correspond to the substrate 102 of FIG. 1 or the substrate 302 of FIG. 3. The conductive via may correspond to the first conductive via 112 of FIG. 1 the second conductive via 114 of FIG. 1, or the conductive via 310 of FIG. 3. The metal layer may correspond to the first metal layer 108 of FIG. 1, the second metal layer 110 of FIG. 1, the first metal layer 306 of FIG. 3, or the second metal layer 308 of FIG. 3. The inductive device may correspond to the inductor formed in the third region 124 of FIG. 1 or the inductor 304 of FIG. 3.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in memory, such as random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM). The memory may include any form of non-transient storage medium known in the art. An exemplary storage medium (e.g., memory) is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal, in the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. A method of forming an electronic device comprising:
forming a first metal layer that directly contacts a first surface of a substrate,
wherein the substrate, including the first surface, is formed from a substantially uniform dielectric material,
wherein the first metal layer contacts a-first conductive via that extends at least partially within the substrate, and
wherein the first metal layer and the first conductive via form at least a portion of an inductive device.

2. The method of claim 1, wherein the first metal layer contacts a second conductive via that extends at least partially within the substrate, and wherein the first conductive via, the first metal layer, and the second conductive via form a portion of a coil of the inductive device.

3. The method of claim 1, further comprising removing a buffer oxide layer from at least a portion of the first surface of the substrate prior to forming the first metal layer.

4. The method of claim 3, wherein the buffer oxide layer is removed from the first conductive via and from the first surface of the substrate prior to forming the first metal layer.

5. The method of claim 1, wherein the dielectric material is an alkaline earth boro-aluminosilicate glass, Gallium Arsenide (GaAs), Indium phosphate (InP), silicon carbide (SiC), a glass-based laminate, sapphire (Al₂O₃), quartz, a ceramic, silicon on insulator (SOI), silicon on sapphire (SOS), high resistivity silicon (HRS), aluminum nitride (AlN), a plastic, or a combination thereof.

6. The method of claim 1, further comprising, prior to forming the first metal layer, forming a second metal layer that contacts a second surface of the substrate opposite the first surface, wherein the first conductive via extends through the substrate, and wherein the second metal layer contacts the first conductive via.

7. The method of claim 1, further comprising, after forming the first metal layer, forming a second metal layer that contacts a second surface of the substrate opposite the first surface, wherein the first conductive via extends through the substrate, and wherein the second metal layer contacts the first conductive via.

8. The method of claim 1, wherein the first metal layer protects against oxidation of a material of the first conductive via.

9. (canceled)

10. The method of claim 1, wherein a buffer oxide layer is not present on the substrate when the first metal layer is formed.

11. The method of claim 1, wherein the substrate has a thickness of at least 0.1 millimeter (mm).

12. The method of claim 1, wherein the first metal layer is formed of aluminum, copper, silver, gold, tungsten, molybdenum, an alloy of aluminum, silver, gold, or tungsten, molybdenum, or a combination thereof.

13. The method of claim 1, wherein the first conductive via is a through glass via.

14. The method of claim 1, wherein the first conductive via is formed of copper, tungsten, silver, gold, an alloy of copper, tungsten, silver, or gold, or a combination thereof.

15. The method of claim 1, further comprising forming the first conductive via using laser drilling, sand blasting, photolithography, light-induced etching, or a combination thereof.

16. The method of claim 1, wherein the first metal layer is formed of a different material than the first conductive via.

17. The method of claim 1, further comprising integrating the inductive device in a diplexer, a low-pass radio frequency (RF) filter, a high-pass RF filter, a notch RF filter, or a harmonic trap circuit.

18. The method of claim 1, wherein forming the first metal layer is initiated by a processor integrated into another electronic device.

19. A device comprising:
a substrate;
a first conductive via that extends at least partially within the substrate; and
a first metal layer that contacts a first surface of the substrate and contacts the first conductive via, wherein the substrate, including the first surface, is formed from a substantially uniform dielectric material, wherein the first metal layer and the first conductive via form at least a portion of an inductive device.

20. The device of claim 19, further comprising a second conductive via that extends at least partially within the substrate, wherein the first metal layer contacts the second conductive via, and wherein the first conductive via, the first metal layer, and the second conductive via form a portion of a coil of the inductive device.

21. The device of claim 19, wherein the dielectric material is an alkaline earth boro-aluminosilicate glass, Gallium Arsenide (GaAs), Indium phosphate (InP), silicon carbide (SiC), a glass-based laminate, sapphire (Al₂O₃), quartz, a ceramic, silicon on insulator (SOI), silicon on sapphire (SOS), high resistivity silicon (HRS), aluminum nitride (AlN), a plastic, or a combination thereof.

22. The device of claim 19, further comprising a second metal layer that contacts a second surface of the substrate opposite the first surface, wherein the first conductive via extends through the substrate, and wherein the second metal layer contacts the first conductive via.

23. The device of claim 19, wherein the first metal layer protects against oxidation of a material of the first conductive via.

24. The device of claim 19, wherein the substrate is an unprotected substrate.

25. The device of claim 19, wherein the substrate has a thickness of at least 0.1 mm.

26. The device of claim 19, wherein the first metal layer is formed of aluminum, copper, silver, gold, tungsten, molybdenum, an alloy of aluminum, silver, gold, tungsten, or molybdenum, or a combination thereof.

27. The device of claim 19, wherein the first conductive via is a through glass via.

28. The device of claim 19, wherein the first conductive via is formed of copper, tungsten, silver, gold, an alloy of copper, tungsten, silver, or gold, or a combination thereof.

29. The device of claim 19, wherein the first conductive via is formed using laser drilling, sand blasting, photolithography, light-induced etching, or a combination thereof.

30. The device of claim 19, wherein the first metal layer is formed of a different material than the first conductive via.

31. The device of claim 19, wherein no buffer oxide layer is present on the first surface of the substrate.

32. The device of claim 19, wherein no buffer oxide layer is present between the first surface of the substrate and the first metal layer.

33. The device of claim 19, wherein the inductive device is included in a diplexer, a low-pass radio frequency (RF) filter, a high-pass RF filter, a notch RF filter, or a harmonic trap circuit.

34. The device of claim 19, further comprising a metal insulator metal (MIM) dielectric layer formed above a side of the first metal layer opposite the substrate, wherein the MIM dielectric layer is formed of SiO₂, SiNₓ, or SiOₓN_{y} using plasma-enhanced chemical vapor deposition (PECVD), formed of Al₂O₃ using physical vapor deposition (PVD) or atomic layer deposition (ALD), formed of ZrO₂ using ALD, formed of Ta₂O₅ by sputtering PVD of Ta before using an anodization process, or a combination thereof.

35. The device of claim 19, integrated in at least one die.

36. The device of claim 19, further comprising an electronic device selected from a set top box, a music player, a video player, an entertainment unit, a navigation device, a communications device, a personal digital assistant (PDA), a fixed location data unit, and a computer, into which the substrate is integrated.

37. A method of forming an electronic device comprising:
a step for forming a conductive via that extends at least partially within a substrate; and
a step for forming a metal layer that directly contacts a surface of the substrate,
wherein the substrate, including the surface, is formed from a substantially uniform dielectric material,
wherein the metal layer contacts the conductive via, and
wherein the metal layer and the conductive via form at least a portion of an inductive device.

38. The method of claim 37, wherein the step for forming the conductive via and the step for forming the metal layer are initiated by a processor integrated into another electronic device.

39. A device comprising:
means for supporting layers;
means for connecting layers that extends at least partially within the means for supporting layers; and
means for conducting, wherein the means for conducting contacts a surface of the means for supporting layers and contacts the means for connecting layers, wherein the means for supporting layers, including the surface, is formed from a substantially uniform dielectric material, wherein the means for conducting and the means for connecting layers form at least a portion of an inductive device.

40. The device of claim 39, integrated in at least one die.

41. The device of claim 39, further comprising an electronic device selected from a set top box, a music player, a video player, an entertainment unit, a navigation device, a communications device, a personal digital assistant (PDA), a fixed location data unit, and a computer, into which the means for supporting layers is integrated.

42. A non-transitory computer readable medium storing instructions that, when executed by a processor, cause the processor to:
initiate formation of a metal layer that contacts a surface of a substrate,
wherein the substrate, including the surface, is formed from a substantially uniform dielectric material,
wherein the metal layer contacts a conductive via that extends at least partially within the substrate, and
wherein the metal layer and the conductive via form at least a portion of an inductive device.

43. The non-transitory computer readable medium of claim 42, further comprising an electronic device selected from a fixed location data unit and a computer, into which the non-transitory computer readable medium is integrated.

44. A method of forming an electronic device comprising:
receiving a data file including design information corresponding to an integrated circuit device; and
fabricating the integrated circuit device according to the design information, wherein the integrated circuit device includes:
a substrate;
a conductive via that extends at least partially within the substrate; and
a metal layer that directly contacts a surface of the substrate and contacts the conductive via, wherein the substrate, including the surface, is formed from a substantially uniform dielectric material, wherein the metal layer and the conductive via form at least a portion of an inductive device.

45. The method of claim 44, wherein the data file has a GERBER format.

46. The method of claim 44, wherein the data file has a GDSII format.

47. The method of claim 1, wherein at least a portion of the metal layer contacts a second conductive via, and further comprising forming a capacitor at least partially by depositing a dielectric layer proximate to the portion of the metal layer that contacts the second conductive via.
